(19) United States
(12) Patent Application Publication
(10) Pub. No.: US 2005/0148111 A1
(43) Pub. Date: Jul. 7, 2005

(54) Method and system for producing resilient solder joints

(75) Inventor: Robert F. Mortan, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/748,480

(22) Filed: Dec. 30, 2003

(51) Int. Cl. H01L 21/44

(52) U.S. Cl. 438/106

(57) ABSTRACT

A method includes mounting an electronic component to a circuit board. Solder paste is applied to a board pad of the circuit board and a terminal pad of an electrical component is aligned with the board pad. The terminal includes a pad feature and a pad base. The solder paste is liquefied to cause the solder paste to flow along the pad feature. Then the solder paste is cooled to form a solder joint. The solder joint bonds the board pad and the pad base and forms a connection between the circuit board and the electrical component. Because this solder joint is subject to reduced stress at interface junctures of the solder joint, the solder joint is more resilient than conventional solder joints.

### TECHNICAL FIELD OF THE INVENTION

This invention relates in general to the production of electronic devices and more particularly to solder mounting electronic components to circuit boards.

### BACKGROUND OF THE INVENTION

Soldering is a common technique for mounting integrated circuits and other components to circuit boards. Solder paste is applied to specific locations on the circuit board where connections with an electronic component are desired. Next, the electronic component is mounted on the solder paste and the solder paste is heated until liquefied. After the liquefied solder paste cools, the solder paste forms a binding, conductive joint between the mounted component and the circuit board.

Once formed, a solder joint is subjected to heat, physical stress, and other forces that exert pressure on the solder joint. Typically, when force is applied to the solder joint, the resulting stress on the solder joint is concentrated at the interface junctures between the terminal pad and the solder joint and between the board pad and the solder joint. Because the solder joint is composed of more brittle material at these interface junctures, the concentration of forces at the interface junctures leads to an increased likelihood that the solder joint will break, disrupting the connection between the circuit board and the electronic component.

### SUMMARY OF THE INVENTION

From the foregoing, it may be appreciated by those skilled in the art that a need has arisen for a method of providing solder joints with improved resilience to stress. In accordance with the present invention, a method and system for applying solder paste to circuit boards are provided that substantially eliminate or reduce at least some of the disadvantages and problems associated with the previous techniques and systems.

According to an embodiment of the present invention, a method for mounting an electronic component to a circuit board includes applying solder paste to a board pad of a circuit board and aligning a terminal pad of an electrical component with the board pad. The terminal pad includes a pad feature and a pad base. The method additionally includes liquefying the solder paste to cause the solder paste to flow along the pad feature and cooling the solder paste to form a solder joint. The solder joint bonds to both the board pad and the solder pad.

In accordance with another embodiment of the present invention, a circuit board assembly includes a circuit board, a component package, and a solder deposit. The circuit board includes a board pad and the component package includes a terminal pad with a pad base and a pad feature. In addition, the solder deposit is capable of flowing along the pad feature when liquefied and forming a solder joint when cooled. The solder joint bonds the pad base and the board terminal.

Important technical advantages of certain embodiments of the present invention include providing solder joints with improved resistance to thermal, mechanical, and other forms of stress. Other important technical advantages of certain embodiments of the present invention include providing solder joints with improved thermal dissipation. Other technical advantages of the present invention will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present invention and for further features and advantages thereof, reference is now made to the following description, taken in conjunction with the accompanying drawings, wherein like reference numerals represent like parts, in which:

FIG. 1 is a diagram illustrating a cross-section of a component package and a circuit board according to a particular embodiment of the present invention;

FIG. 2 illustrates a cross sectional view of a circuit board during a first step in a method for mounting a component package to the circuit board;

FIG. 3 illustrates a cross sectional view of the component package and the circuit board during a second step in the method;

FIG. 4 illustrates a cross sectional view of the component package and the circuit board during a third step in the method;

FIGS. 5A-5B illustrate a terminal pad and a solder joint, respectively, according to a particular embodiment;

FIGS. 6A-6B illustrate a terminal pad and a solder joint, respectively, according to another embodiment; and

FIG. 7 is a flowchart detailing a method for mounting an electronic component to a circuit board according to a particular embodiment of the present invention.

### DETAILED DESCRIPTION OF THE INVENTION

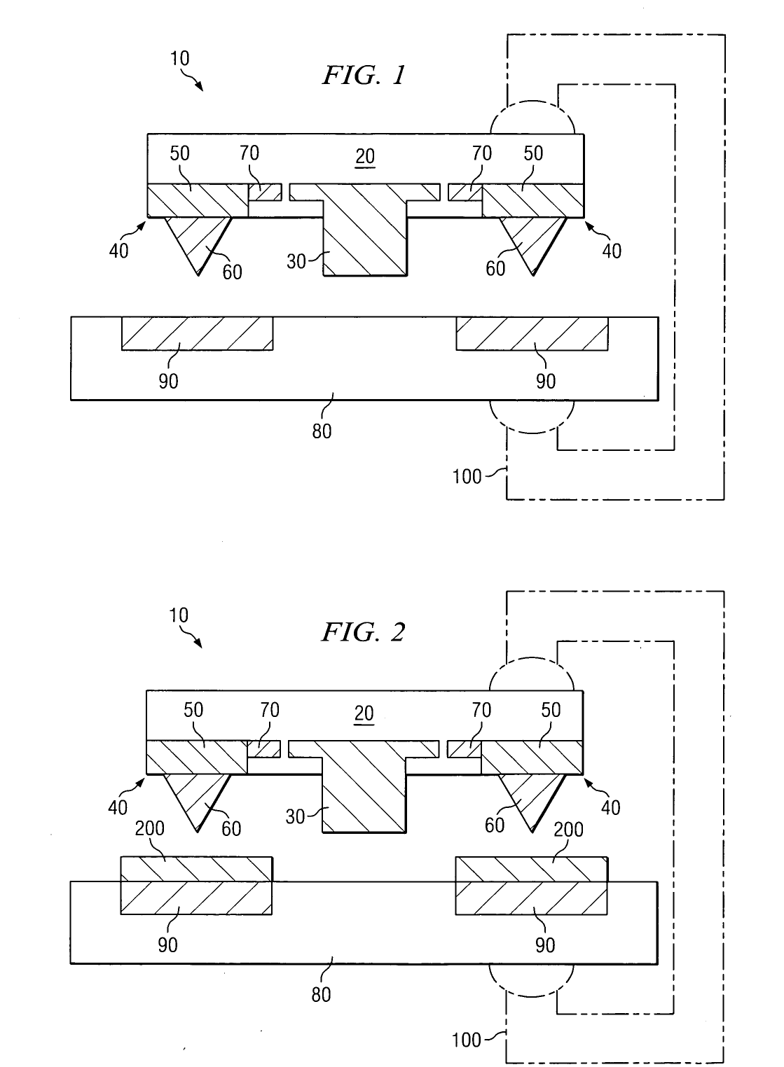

FIG. 1 illustrates a system 10 for mounting electronic components to a circuit board 80 according to a particular embodiment. System 10 includes a component package 20, a circuit board 80, and an operator 100. Operator 100 applies solder paste to circuit board 80 to form solder joints connecting circuit board 80 and component package 20. More specifically, operator 100 brings component package 20 into contact with liquefied solder paste deposits on circuit board 80. Pad feature 60 then directs a flow of liquefied solder towards component package 20 to form a solder joint of a particular shape. When this solder joint is later subjected to various forms of stress, the shape of the solder joint causes the stress to be distributed so that the stress is concentrated in the center of the solder joint. By contrast, in conventional solder joints, applied stress will be concentrated near the interface junctures of the solder joint and the circuit board or terminal pad. Because the center of the solder joint is more ductile than the areas near the solder joint interface junctures, system 10 may produce more resilient solder joints than are produced using conventional techniques.

Component package 20 represents an integrated circuit package or other electronic device. Examples, of component package 20 include, but are not limited to, a Quad Flat No-lead (QFN) and Small Outline No-lead (SON) package. Component package 20 includes leadframe 30 and terminal pads 40.

Leadframe 30 serves as a platform for electronic devices, such as a silicon die of an integrated circuit or other semiconductor devices. Leadframe 30 may include wires or other conductive elements, connecting semiconductor devices mounted on leadframe 30 to terminal pads 40. Leadframe 30 may be composed of metal or any other suitable material.

Terminal pads 40 provide a connection between elements of component package 20, such as a semiconductor device mounted on component package 20, and circuit board 80. Terminal pads 40 may directly connect to semiconductor devices mounted on component package 20 or may couple to wires or other conductive elements that connect to the semiconductor devices.

Each terminal pad 40 includes a pad base 50, a pad feature 60, and a pad anchor 70. Pad base 50 couples circuit board 80 to semiconductor devices mounted to component package 20 through solder joints formed between component package 20 and circuit board 80. Pad base 50 also supports pad feature 60. Pad base 50 may be composed of copper, gold, or any other suitable conductive material.

Pad feature 60 guides the formation of solder joints formed between component package 20 and circuit board 80. When component package 20 is mounted on solder paste, pad feature 60 may cause the molten solder to form solder joints having a particular shape and particular characteristics, as described further below. Pad feature 60 may be formed in any appropriate shape and may be composed of any suitable material. Moreover, the shape, composition, and other characteristics of pad feature 60 may dictate the shape and other characteristics of the resulting solder joint. In a particular embodiment, pad feature 60 has a conic shape. Additionally, pad feature 60 may be formed using any suitable techniques. In a particular embodiment, pad feature 60 may be formed by etching a surface protruding from pad base 50.

Pad anchor 70 prevents physical stress or other forces from separating terminal pad 40 from component package 20. Pad anchor 70 connects to pad base 50 and may represent an integrated portion of pad base 50 or a separate element connected to pad base 50. Pad anchor 70 may be made of any suitable material appropriate for anchoring pad base 50 to leadframe 30.

Circuit board 80 serves as a mounting base for electronic components, such as component package 20, and includes board pads 90. Circuit board 80 couples to mounted electronic components through soldered connections. Circuit board 80 provides electrical connections between the various electronic components mounted on circuit board 80 through wires or other conductive elements. Circuit board 80 may be composed of plastic, glass, or any other suitable material.

Board pads 90 couple circuit board 80 to component package 20 through solder joints formed between component package 20 and circuit board 80. Circuit board 80 then provides electrical connections between component package 20 and other electronic components through wires or other conductive elements that connect various board pads 90. Board pads 90 may be composed of copper or any other suitable conductive material.

Operator 100 represents a human operator or mechanical or electrical equipment capable of manipulating component package 20 and circuit board 80 as appropriate to form solder joints. For example, operator 100 may represent a machine that includes a solder dispenser and that is capable of applying solder paste to circuit board 80 and positioning component package 20 and circuit board 80 as needed to form solder joints. Alternatively, operator 100 may represent a human who manually applies solder to circuit board 80 and aligns component package 20 and circuit board 80 so that solder joints will form.

FIGS. 2-4 illustrate a method of forming solder joints to mount component package 20 to circuit board 80. Although FIGS. 2-4 illustrate a method that forms solder joints of a particular shape, pad features 60 may be designed to create solder joints of any appropriate shape.

FIG. 2 illustrates a first step in the operation of system 10. Operator 100 applies solder paste to circuit board 80 to form solder paste deposits 200. Solder paste deposits 200 may be formed from any suitable type of solder paste, for example, conventional reflow solder paste. Similarly, solder paste deposits 200 may be applied using any suitable techniques, including conventional techniques for the application of solder. For example, operator 100 may represent a human that operates, or machinery that includes, a solder applicator capable of dispensing a continuous flow of solder paste as the applicator moves across the length of circuit board 80. By inserting a solder stencil between the solder applicator and circuit board 80, operator 100 can apply solder paste deposits 200 to circuit board 80 in predetermined locations to provide a desired pattern of connectivity to electronic components mounted on circuit board 80. Depending on the characteristics of the particular pad features 60 included in system 10, solder paste deposits 200 formed for use with component package 20 may utilize more, or less, solder paste than those formed for use with conventional electronic components.

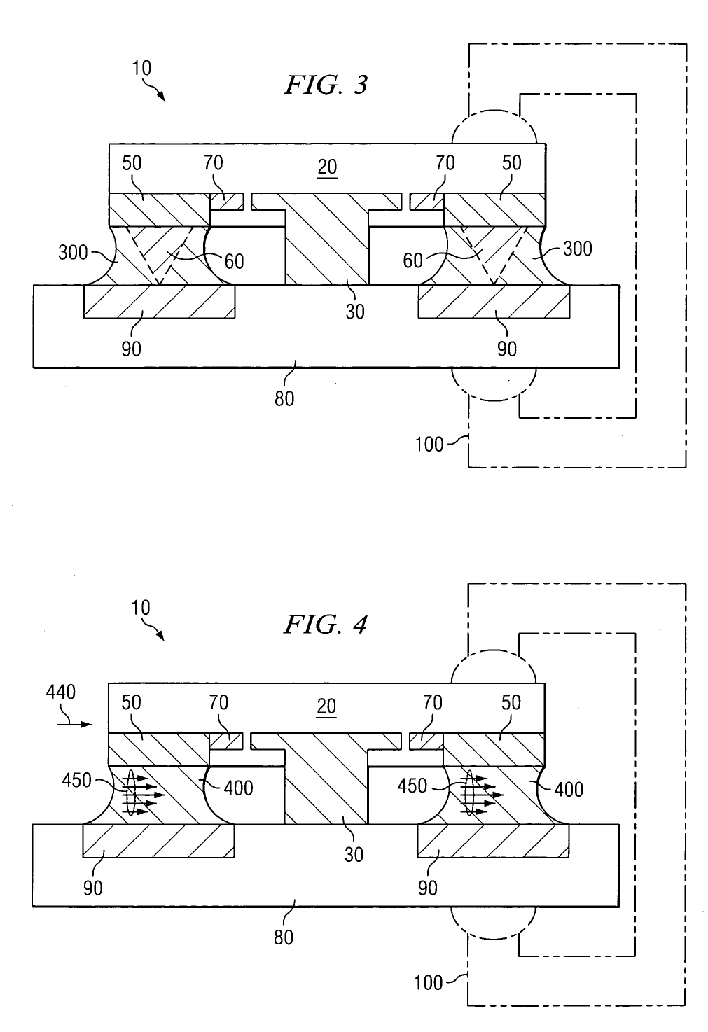

FIG. 3 illustrates a second step in the operation of system 10. Operator 100 aligns pad features 60 with board pads 90 so that pad features 60 abut board pads 90. Aligning pad features 60 and board pads 90 may include rotating component package 20 and/or circuit board 80, bringing component package 20 and circuit board 80 into physical contact, or coordinating the position of component package 20 and/or circuit board 80 in any other appropriate manner. For example, for the conic shape of pad feature 60 illustrated in FIG. 3, aligning pad features 60 with board pads 90 includes lowering pad features 60 until each pad feature 60 touches a particular board pad 90 near a center of the board pad 90.

After operator 100 aligns terminal pads 40 and board pads 90, operator 100 liquefies solder paste deposits 200 using any suitable appropriate technique. For example, operator 100 may liquefy solder paste deposits 200 by melting solder paste deposits 200 using conventional one-time reflow techniques. Once solder paste deposits 200 are liquefied, pad features 60 will direct a flow of liquefied solder due to surface tension and wetting effects toward the surface of terminal pad 40 to form liquefied deposits 300. As noted above, certain characteristics of pad features 60 may determine characteristics of liquefied deposits 300, such as a shape of liquefied deposits 300.

FIG. 4 illustrates a third step in the operation of system 10. After operator 100 forms liquefied deposits 300, operator 100 cools liquefied deposits 300 to form solder joints 400. Again, characteristics of pad feature 60 may determine the shape and other characteristics of solder joints 400. Under certain circumstances, the conic shape of pad feature 60, the surface tension of the liquefied solder, and other properties of the solder and pad feature 60 cause pad feature 60 to produce a solder joint 400 with an hourglass shape. The hourglass shape includes an approximately cylindrical shape with a varying diameter. Moving from one interface juncture of solder joint 400 to the other, the diameter decreases, reaching a minimum near the center of solder joint 400, and then increases again, as shown in FIG. 4.

One result of the hourglass shape of solder joint 400 may be that when a force is exerted on solder joint 400 parallel to circuit board 80 and component package 20, the resulting stress on solder joint 400 will be concentrated near the middle of solder joint 400. As a result of the intermetallic composition of solder near the interface junctures of solder joint 400, the center of solder joint 400 is more ductile than the areas near these interface junctures. Thus, the hourglass shape of solder joint 400 may result in solder joint 400 being more resilient to forces such as stress, shock, or other forms of stress, than conventional solder joints. For example, a force 440 applied to package component 20 parallel to circuit board 80 results in a stress distribution in solder joints 400 as shown by arrows 450. The magnitude of the stress at each point along solder joint 400 is shown by the length of arrow 450 at that point. As illustrated by FIG. 4, stress resulting from force 440 is concentrated near the center of solder joint 400 and not at the interface junctures.

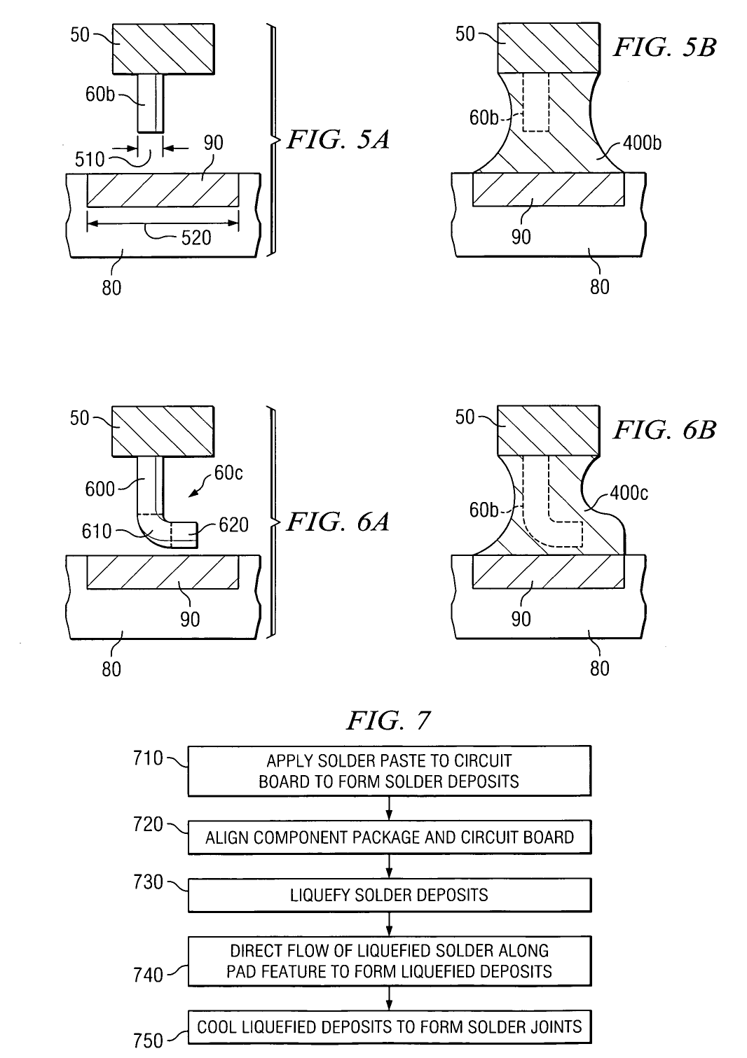

FIGS. 5A and 5B illustrate an alternative shape for pad feature 60 and solder joint 400, respectively. As shown in FIG. 5A, pad feature 60 represents a cylindrical peg, peg pad feature 60b. Peg pad feature 60b has a width, peg width 510, less than a width of board pad 90, board pad width 520. Based, at least in part, on the differences in peg width 510 and board pad width 520 and on the shape of peg pad feature 60b, peg pad feature 60b may also create a solder joint with an approximately hourglass shape, solder joint 400b, as shown in FIG. 5B.

FIGS. 6A and 6B illustrate another alternative shape for pad feature 60 and solder joint 400, respectively. As illustrated in FIG. 6A, pad feature 60 represents a J-hook pad feature 60c that includes a vertical section 600, a horizontal section 620, and an arcuate section 610. The vertical section 600 extends perpendicularly from pad base 50. Horizontal section 620 extends along a parallel axis to pad base 50. Arcuate section 610 provides a curved connection between vertical section 600 and horizontal section 620. Depending on the configuration of system 10, J-hook pad feature 60c may create a solder joint with either a J-hook or hour glass shape, solder joint 400c, as shown in FIG. 6B. Under certain circumstances, when a force is exerted on solder joint 400c parallel to circuit board 80 and component package 20, stress on solder joint 400c is concentrated near the middle of solder joint 400 in a similar fashion to that described above with respect to FIG. 4. Although FIGS. 5A and 6A show two alternative embodiments of pad feature 60, in general, pad feature 60 may represent any shape appropriate for forming a solder joint 400 in which force is redistributed away from the interface junctures of solder joint 400.

FIG. 7 is a flow chart detailing steps of a method for mounting electronic components to a circuit board 80 according to a particular embodiment. At step 710, operator 100 applies solder paste to circuit board 80 to form solder paste deposits 200. Operator 100 then aligns component package 20 and circuit board 80 at step 720. After aligning component package 20 with circuit board 80, operator 100 liquefies solder paste deposits 200 at step 730. At step 740, pad feature 60 directs a flow of liquefied solder to pad base 50 to form liquefied deposits 300. Operator 100 cools liquefied deposits 300 to form solder joints 400 at step 750.

Although the present invention has been described with several embodiments, a myriad of changes, variations, alterations, transformations, and modifications may be suggested to one skilled in the art, and it is intended that the present invention encompass such changes, variations, alterations, transformations, and modifications as fall within the scope of the appended claims.

1. A method for mounting an electronic component to a circuit board comprising:
applying solder paste to a board pad of a circuit board;
aligning a terminal pad of an electrical component with the board pad, wherein the terminal pad comprises a pad feature and a pad base;
liquefying the solder paste to cause the solder paste to flow along the pad feature; and
cooling the solder paste to form a solder joint, the solder joint bonding the board pad and the pad base.

2. The method of claim 1, wherein the solder joint comprises an hourglass shape.

3. The method of claim 1, wherein the pad feature comprises a J-hook shape.

4. The method of claim 1, wherein the board pad comprises a first width, and wherein the pad feature comprises a peg, wherein the peg comprises a second width, the first width being greater than the second width.

5. The method of claim 1, wherein the pad feature comprises a conic shape.

6. The method of claim 1, wherein and wherein aligning the terminal pad with the board pad comprises aligning an apex of the pad feature with the board pad.

7. The method of claim 1, further comprising etching the terminal pad to form the pad feature prior to aligning the terminal with the board pad.

8. The method of claim 1, wherein the electrical component comprises a Quad Flat No-lead (QFN) package.

9. The method of claim 1, wherein the electrical component comprises a Small Outline No-lead (SON) package.

10. A circuit board assembly comprising:
a circuit board, the circuit board comprising a board pad;
a component package, the component package comprising a terminal pad, wherein the terminal pad includes a pad feature and a pad base and wherein the pad feature is aligned with the board pad; and
a solder deposit, wherein the solder deposit is operable to flow along the pad feature when liquefied and to form a solder joint when cooled, the solder joint abutting the pad base and the board base.

11. The circuit board assembly of claim 10, wherein the solder deposit is further operable to form the solder joint when cooled, the solder joint comprising an hourglass shape.

12. The circuit board assembly of claim 10, wherein the pad feature comprises a J-hook shape.

13. The circuit board assembly of claim 10, wherein the board pad comprises a first width, and wherein the pad feature comprises a peg, wherein the peg comprises a second width, the first width being greater than the second width.

14. The circuit board assembly of claim 10, wherein the pad feature comprises a conic shape.

15. The circuit board assembly of claim 10, wherein aligning the terminal pad with the board pad comprises aligning an apex of the pad feature with the board pad.

16. The circuit board assembly of claim 10, wherein the component package comprises a Quad Flat No-lead (QFN) package.

17. The circuit board assembly of claim 10, wherein the component package comprises a Small Outline No-lead (SON) package.

18. A circuit board assembly comprising:
a circuit board, the circuit board comprising a board pad;
a component package, the component package comprising a terminal pad, wherein the terminal pad includes a pad feature and a pad base; and
a solder joint, wherein the solder joint comprises an hourglass shape and couples the board pad to the terminal pad.

19. The circuit board assembly of claim 18, wherein the component package comprises a Quad Flat No-lead (QFN) package.

20. The circuit board assembly of claim 18, wherein the component package comprises a Small Outline No-lead (SON) package.
